(19) United States
(12) Patent Application Publication
(10) Pub. No.: US 2017/0089069 A1
(43) Pub. Date: Mar. 30, 2017

(54) AIR-PERMEABLE RADIANT BARRIER SHEET HAVING IGNITION PREVENTION AND RADIATION REFLECTION FUNCTIONS, AND WOOD PANEL COMPRISING SAME

(71) Applicants: SKC INC., Covington, GA (US); SKC CO., LTD., Suwon-si (KR)

(72) Inventors: Mary KLIMA, Lawrenceville, GA (US); Eugene JUNG, Lawrenceville, GA (US); Teahoung JEONG, Snellville, GA (US); Jae Hyeuk JEONG, Duluth, GA (US); Dae Yong SHIN, Duluth, GA (US)

(73) Assignees: SKC INC., Covington, GA (US); SKC CO., LTD., Suwon-si (KR)

(21) Appl. No.: 15/274,487

(22) Filed: Sep. 23, 2016

Related U.S. Application Data
(60) Provisional application No. 62/222,813, filed on Sep. 24, 2015.

(51) Int. Cl. E04C 2/52; B32B 27/36; E04C 2/24; C23C 14/24; C23C 14/20; B32B 21/08; B32B 3/26

(52) U.S. Cl. CPC E04C 2/52; B32B 21/08; B32B 27/36; B32B 3/266; C23C 14/24; C23C 14/20; E04C 2/24; B32B 2255/10; B32B 2255/205; B32B 2255/26; B32B 2255/28; B32B 2307/3065; B32B 2307/416; B32B 2307/724; B32B 2307/304; B32B 2419/06

(57) ABSTRACT

The present invention relates to a radiant barrier sheet and a wood panel comprising same. The radiant barrier sheet comprises a polymer film, a first radiant reflective layer disposed on the polymer film, and a first protective layer disposed on the first radiant reflective layer, wherein the radiant barrier sheet has through-holes configured to penetrate through the polymer film and the first radiant reflective layer, the number of the through-holes ranges from 1 to 10 per 1 cm², a planar area of the through-holes ranges from about 20,000 μm² to about 200,000 μm² per 1 cm², and a diameter of the through-hole ranges from about 80 μm to about 300 μm.

### TECHNICAL FIELD

The present invention relates to an air-permeable radiant barrier sheet having ignition prevention and radiation reflection functions, and a wood panel comprising same.

### BACKGROUND ART

A lignocellulose-based composite article includes an oriented strand board (OSB), an oriented strand lumber (OSL), a particle board (PB), a scrimber, an agrifiber board, a chip board, a flake board, a fiber board, or a medium density fiber board (MDF). The lignocellulose-based composite article may be produced by blending lignocellulose-based pieces with a binder composition (e.g., resin) or by sprinkling the binder composition over the lignocellulose-based pieces. In this case, the lignocellulose-based pieces are tumbled or stirred in a blender or a similar device.

A wood panel including such lignocellulose-based composite article should have functions of preventing ignition caused by an electricity leakage and insulating heat through radiation reflection, and air permeability.

### DISCLOSURE OF INVENTION

### Solution to Problem

In one embodiment, the present invention provides a radiant barrier sheet comprising: a polymer film; a first radiant reflective layer disposed on the polymer film; and a first protective layer disposed on the first radiant reflective layer,

wherein the radiant barrier sheet has through-holes configured to penetrate through the polymer film and the first radiant reflective layer, the number of the through-holes ranges from 1 to 10 per 1 cm², a planar area of the through-holes ranges from about 20,000 μm² to about 200,000 μm² per 1 cm², and a diameter of the through-hole ranges from about 80 μm to about 300 μm.

In another embodiment, the present invention provides a wood panel comprising: a wood base; and a radiant barrier sheet bonded to the wood base,

wherein the radiant barrier sheet comprises a polymer film disposed on the wood base; a first radiant reflective layer disposed on the polymer film; and a first protective layer disposed on the first radiant reflective layer,

wherein the radiant barrier sheet has through-holes configured to penetrate through the polymer film and the first radiant reflective layer, the number of the through-holes ranges from 1 to 10 per 1 cm², a planar area of the through-holes ranges from about 20,000 μm² to about 200,000 μm² per 1 cm², and a diameter of the through-hole ranges from about 80 μm to about 300 μm.

In yet another embodiment, the present invention provides a radiant barrier sheet comprising: a polymer film; a first radiant reflective layer disposed on the polymer film; and a first protective layer disposed on the first radiant reflective layer,

wherein the radiant barrier sheet has through-holes configured to penetrate through the polymer film and the first radiant reflective layer, the number of the through-holes ranges from 1 to 10 per 1 cm², a diameter of the through-holes ranges from about 80 μm to about 300 μm, and the first protective layer covers both an inner surface of the through-hole of the first radiant reflective layer and an inner surface of the through-hole of the polymer film.

### Advantageous Effects of Invention

A radiant barrier sheet according to the embodiments of the present invention has improved moisture and air permeability, and may effectively block solar heat and reflect solar radiation. Also, a wood panel comprising the radiant barrier sheet may easily discharge internal moisture to the outside.

Particularly, a wood panel according to an embodiment may be used in a roof of a house. In this case, the wood panel may effectively block solar heat and reflect solar radiation. Further, the wood panel may have an excellent ignition prevention effect in comparison to a conventional wood panel in case of an electricity leakage or a stroke of lightning.

### BRIEF DESCRIPTION OF DRAWINGS

FIG. 1 is an exploded perspective view illustrating a wooden panel according to one embodiment of the present invention.

FIG. 2 is a cross-sectional view illustrating a cross section of the wooden panel according to one embodiment of the present invention.

FIG. 3 is a cross-sectional view illustrating a cross section of a wooden panel according to another embodiment of the present invention.

FIG. 4 is a cross-sectional view illustrating a cross section of a wooden panel according to an alternative embodiment of the present invention.

### BEST MODE FOR CARRYING OUT THE INVENTION

In the description of embodiments, it will be understood that when a film, membrane, panel, or layer is referred to as being “on” or “under” another film, membrane, panel, or layer, it may be “directly” on or under the other film, membrane, panel or layer, or an intervening element (“indirectly”) may be present there between. Further, the reference about on/under each element will be determined based on the drawings. In the drawings, the size of each element may be exaggerated for convenience in description and clarity, and the size of each element does not entirely reflect its actual size.

A radiant barrier sheet according to an embodiment of the present invention may comprise a polymer film; a first radiant reflective layer disposed on the polymer film; and a first protective layer disposed on the first radiant reflective layer, wherein the radiant barrier sheet has through-holes configured to penetrate through the polymer film and the first radiant reflective layer, the number of the through-holes ranges from 1 to 10 per 1 cm², a planar area of the through-holes ranges from about 20,000 μm² to about 200,000 μm² per 1 cm², and a diameter of the through-hole ranges from about 80 μm to about 300 μm.

A wood panel according to an embodiment of the present invention may comprises a wood base; and a radiant barrier sheet bonded to the wood base, wherein the radiant barrier sheet comprises a polymer film disposed on the wood base; a first radiant reflective layer disposed on the polymer film; and a first protective layer disposed on the first radiant reflective layer, wherein the radiant barrier sheet has through-holes configured to penetrate through the polymer film and the first radiant reflective layer, the number of the through-holes ranges from 1 to 10 per 1 cm², a planar area of the through-holes ranges from about 20,000 μm² to about 200,000 μm² per 1 cm², and a diameter of the through-hole ranges from about 80 μm to about 300 μm.

A radiant barrier sheet according to the present invention may comprise a polymer film; a first radiant reflective layer disposed on the polymer film; and a first protective layer disposed on the first radiant reflective layer, wherein the radiant barrier sheet has through-holes configured to penetrate through the polymer film and the first radiant reflective layer, the number of the through-holes ranges from 1 to 10 per 1 cm², a diameter of the through-holes ranges from about 80 μm to about 300 μm, and the first protective layer covers both an inner surface of the through-hole of the first radiant reflective layer and an inner surface of the through-hole of the polymer film.

In order to include the through-holes having a planar area of 20,000 μm²/cm² or more, the radiant barrier sheet may comprise one or more through-holes having a diameter of about 50 μm to about 1,000 μm in the area of 1 cm².

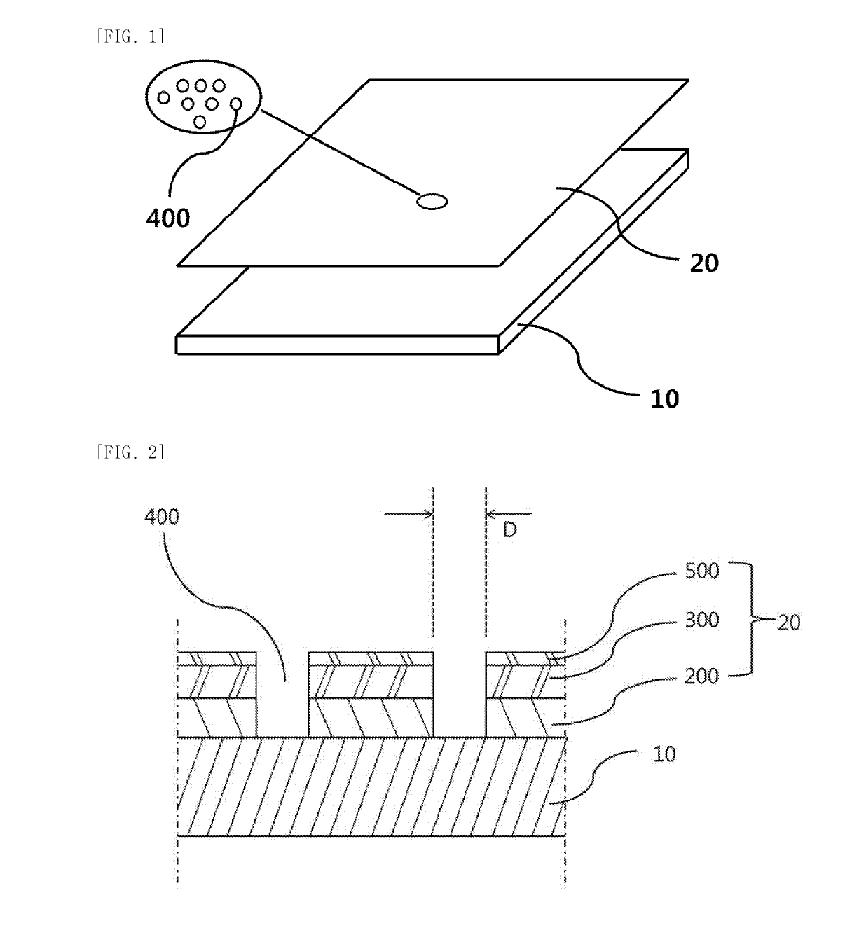

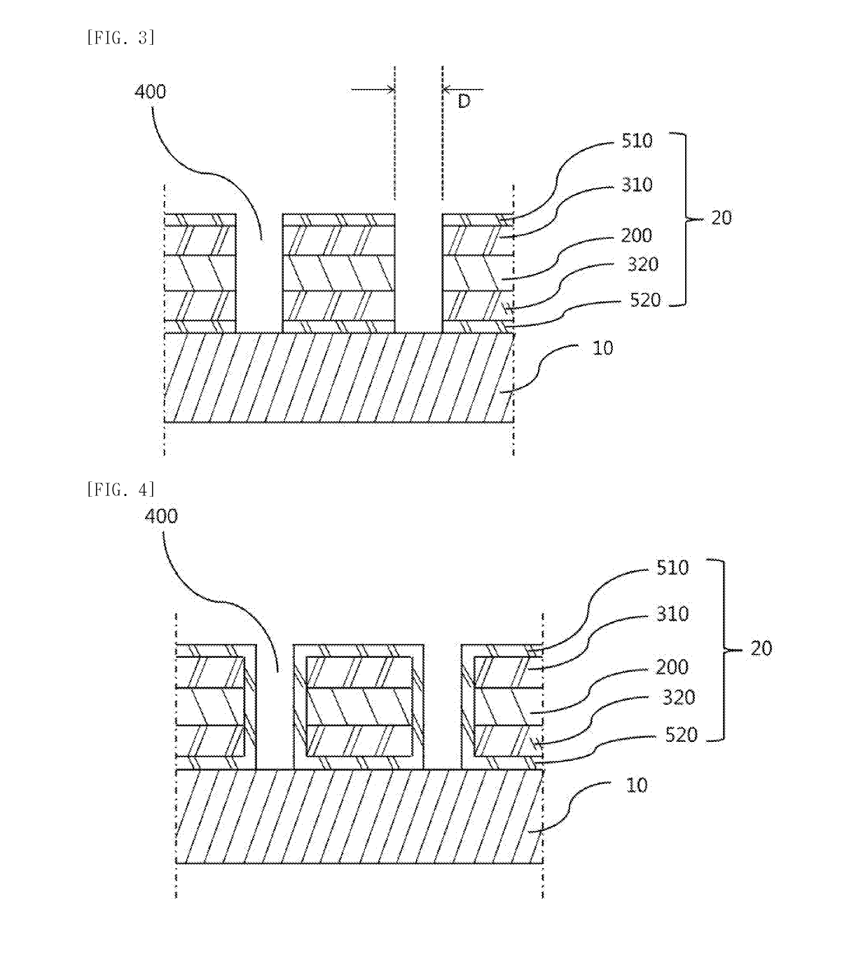

FIG. 1 is an exploded perspective view illustrating a wooden panel according to one embodiment of the present invention. FIG. 2 is a cross-sectional view illustrating a cross section of the wooden panel according to one embodiment of the present invention. FIG. 3 is a cross-sectional view illustrating a cross section of a wooden panel according to another embodiment of the present invention. FIG. 4 is a cross-sectional view illustrating a cross section of a wooden panel according to an alternative embodiment of the present invention.

Referring to FIGS. 1 and 2, the wood panel according to one embodiment of the present invention may comprise a wood base 10 and a radiant barrier sheet 20.

The wood base 10 may comprise wood. Specifically, the wood base 10 may comprise a material made by lumber. Particularly, the wood base 10 may comprise processed wood itself or a material extracted from the wood. In particular, the wood base 10 may be a lignocellulose-based composite material.

The lignocellulose-based composite material may be produced by blending lignocellulose-based pieces with a binder composition (e.g., resin) or by sprinkling the binder composition over the lignocellulose-based pieces. Also, the lignocellulose-based pieces may be formed by tumbling or stirring in a blender or a similar device.

For example, the lignocellulose-based composite material may be one selected from the group consisting of an oriented strand board (OSB), an oriented strand lumber (OSL), a particle board (PB), a scrimber, an agrifiber board, a chip board, a flake board, a fiber board, and a medium density fiber board (MDF).

The wood base 10 may have a plate shape. Specifically, the wood base 10 may have a plate shape with a thickness of about 1 mm to about 10 cm.

The radiant barrier sheet 20 may be disposed on at least one surface of the wood base 10. Specifically, the radiant barrier sheet 20 may be disposed on a top surface and/or a bottom surface of the wood base 10. Particularly, the radiant barrier sheet 20 may be directly stacked on the top surface and/or the bottom surface of the wood base 10.

In particular, the radiant barrier sheet 20 may be bonded to the top surface and/or the bottom surface of the wood base 10 by an adhesive. That is, an adhesive layer may be inserted between the wood base 10 and the radiant barrier sheet 20.

The radiant barrier sheet 20 may be directly stacked on the top surface and/or the bottom surface of the wood base 10. Specifically, the radiant barrier sheet 20 may be laminated on the top surface and/or the bottom surface of the wood base 10.

The radiant barrier sheet 20 has a through-hole 400. The through-hole 400 penetrates through the polymer film and the first radiant reflective layer. Particularly, the through-hole 400 may have various shapes such as a circular, elliptical, polygonal, star, or torn shape.

A diameter of the through-hole 400 may be in a range of about 50 μm to about 1,000 μm. Specifically, the diameter of the through-hole 400 may be in a range of about 50 μm to about 750 μm. Particularly, the diameter of the through-hole 400 may be in a range of about 70 μm to about 500 μm. More specifically, the diameter of the through-hole 400 may be in a range of about 80 μm to about 300 μm. In the case where the through-hole 400 does not have a circular shape, the diameter of the through-hole 400 is defined as a diameter of a hypothetical circular-shaped through-hole having the same planar area as the through-hole 400.

The number of the through-holes 400 may be in a range of about 1 to about 20 per 1 cm². Specifically, the number of the through-holes 400 may be in a range of about 1 to about 15 per 1 cm². The number of the through-holes 400 may be in a range of about 1 to about 10 per 1 cm². Particularly, the number of the through-holes 400 may be in a range of about 1 to about 7 per 1 cm². More specifically, the number of the through-holes 400 may be in a range of about 2 to about 5 per 1 cm².

A planar area of the through-hole 400 may be in a range of about 20,000 μm² to about 200,000 μm² per 1 cm². Specifically, the planar area of the through-hole 400 may be in a range of about 30,000 μm² to about 200,000 μm² per 1 cm². Particularly, the planar area of the through-hole 400 may be in a range of about 40,000 μm² to about 200,000 μm² per 1 cm². More specifically, the planar area of the through-hole 400 may be in a range of about 100,000 μm² to about 200,000 μm² per 1 cm².

The radiant barrier sheet 20 may have has the above-described number of through-holes 400 having the above-described diameter. Accordingly, the radiant barrier sheet 20 may have improved moisture permeability performance.

A moisture permeability of the radiant barrier sheet 20 may be about 10 perm or more. Specifically, the moisture permeability of the radiant barrier sheet 20 may be in a range of about 10 perm to about 1,000 perm. Particularly, the moisture permeability of the radiant barrier sheet 20 may be about 15 perm or more. The moisture permeability of the radiant barrier sheet 20 may be about 20 perm or more. Particularly, the moisture permeability of the radiant barrier sheet 20 may be about 25 perm or more.

The radiant barrier sheet 20 may comprise a polymer film 200 and a radiant reflective layer 300.

The polymer film 200 may comprise a polyester-based resin, a fluorine-based resin, a polyethylene-based resin, a polypropylene-based resin, or an acrylic resin. Specifically, the polymer film 200 may be a polyester film.

The polyester film may comprise a polyester resin as a main component. Specifically, the polyester film may comprise 80 wt % or more of the polyester resin. Particularly, the polyester film may comprise 90 wt % or more of the polyester resin. More specifically, the polyester film may comprise 99 wt % or more of the polyester resin.

The polyester resin may comprise a diol component and a dicarboxylic acid component. Specifically, the polyester resin may comprise about 95 mol % or more of the diol component and the dicarboxylic acid component. Particularly, the polyester resin may be formed of the diol component and the dicarboxylic acid component. More particularly, the diol component and the dicarboxylic acid component may be subjected to a transesterification reaction and then polymerized to form the polyester resin.

Specific examples of the diol component may include ethylene glycol, 1,4-cyclohexanedimethanol, 1,3-propanediol, 1,2-octanediol, 1,3-octanediol, 2,3-butanediol, 1,3-butanediol, 1,4-butanediol, 1,5-pentanediol, 2,2-dimethyl-1,3-propanediol (neopentyl glycol), 2-butyl-2-ethyl-1,3-propanediol, 2,2-diethyl-1,5-pentanediol, 2,4-diethyl-1,5-pentanediol, 3-methyl-1,5-pentanediol, 1,1-dimethyl-1,5-pentanediol, and a mixture thereof. Specifically, the diol component may comprise about 80 mol % or more of the ethylene glycol. More specifically, the diol component may comprise about 90 mol % or more of the ethylene glycol. Particularly, the diol component may comprise about 95 mol % or more of the ethylene glycol. More particularly, the diol component may comprise about 99 mol % or more of the ethylene glycol.

Specific examples of the dicarboxylic acid component may include an aromatic dicarboxylic acid such as terephthalic acid, dimethylterephthalic acid, isophthalic acid, naphthalenedicarboxylic acid, and orthophthalic acid; an aliphatic dicarboxylic acid such as adipic acid, azelaic acid, sebacic acid, and decanedicarboxylic acid; an alicyclic dicarboxylic acid; and an esterified compound thereof. Specifically, the dicarboxylic acid component may comprise about 80 mol % or more of the aromatic dicarboxylic acid. More specifically, the dicarboxylic acid component may comprise about 80 mol % or more of the terephthalic acid. Particularly, the dicarboxylic acid component may comprise about 90 mol % or more of the terephthalic acid. More particularly, the dicarboxylic acid component may comprise about 95 mol % or more of the terephthalic acid. Specifically, the dicarboxylic acid component may comprise about 99 mol % or more of the terephthalic acid.

The polyester film may comprise polyethylene terephthalate. Specifically, the polyester film may comprise 90 wt % or more of the polyethylene terephthalate. More specifically, the polyester film may comprise 95 wt % or more of the polyethylene terephthalate. Particularly, the polyester resin may be formed of the polyethylene terephthalate.

A thickness of the polymer film may be about 5 μm or more. Specifically, the thickness of the polymer film may be in a range of about 5 μm to about 100 μm. Particularly, the thickness of the polymer film may be in a range of about 7 μm to about 75 μm. More specifically, the thickness of the polymer film may be in a range of about 9 μm to about 35 μm.

The polymer film may be stretched about 2 times to about 6 times in a machine direction. Specifically, the polymer film may be stretched about 2.5 times to about 4 times in the machine direction.

Also, the polymer film may be stretched about 2 times to about 6 times in a tenter direction. Specifically, the polymer film may be stretched about 2.5 times to about 4 times in the tenter direction.

The radiant reflective layer 300 is disposed on the polymer film 200. Specifically, the radiant reflective layer 300 may be formed directly on the polymer film 200.

The radiant reflective layer 300 may be disposed on a bottom surface of the polymer film 200. That is, the radiant reflective layer 300 may be disposed between the polymer film 200 and the wood base 10.

A thermal emittance of the radiant barrier sheet 20 may be 80% or more. Specifically, the thermal emittance of the radiant barrier sheet 20 may be 85% or more. More specifically, the thermal emittance of the radiant barrier sheet 20 may be about 90% or more.

The wood panel according to an embodiment of the present invention may be stacked in multiple layers and transported. In the case where a thin radiant reflective layer is formed, the radiant reflective layer exposed to the outside in the process of being stacked in multiple layers and transported may be damaged by scratches.

As illustrated in FIG. 3, radiant reflective layers 310 and 320 may be disposed on a top surface and a bottom surface of the polymer film 200. That is, the first radiant reflective layer 310 may be disposed on the top surface of the polymer film 200, and the second radiant reflective layer 320 may be disposed on the bottom surface of the polymer film 200.

In the case where the radiant reflective layers 310 and 320 are included on both surfaces of the polymer film 200, even if the first radiant reflective layer 310 exposed to the outside is damaged, radiant reflective performance of the wood panel can be maintained due to the second radiant reflective layer 320. Also, radiant heat passing through the first radiant reflective layer 310 may be reflected by the second radiant reflective layer 320. Thus, the radiant barrier sheet 20 may have improved radiant heat reflective performance.

The radiant reflective layer 300 may reflect radiant heat. Specifically, the radiant reflective layer 300 may reflect radiant heat from the inside or outside of a building.

The radiant reflective layer 300 may comprise a metal. Specifically, the radiant reflective layer 300 may be a metal thin film. More specifically, the radiant reflective layer 300 may be a thin film formed of a metal such as aluminum or copper.

The radiant reflective layer 300 may have a thickness so that an optical density may be 1.0 or more. Specifically, the radiant reflective layer 300 may have a thickness so that an optical density is 1.0 to 3.5 or 2.0 to 3.0. In the case where the radiant reflective layer has a thickness with an optical density of less than 1.0, the radiant reflective performance is reduced, and, in the case where the radiant reflective layer has a thickness with an optical density of greater than 3.5, an improvement in radiant heat reflective efficiency is very small compared to the increase in the thickness of the radiant reflective layer.

The through-hole 400 penetrates through the radiant reflective layer 300 and the polymer film 200. Specifically, the through-hole 400 may penetrate through the polymer film 200, the radiant reflective layer 300, and a protective layer 500.

Further, in the case where the radiant barrier sheet 20 is bonded to the wood base 10 by an adhesive layer, the adhesive layer may also have a hole corresponding to the through-hole 400. Specifically, one surface of the radiant barrier sheet 20 having the through-hole 400 may be coated with an adhesive to form the adhesive layer. In this case, the adhesive may be coated to allow the through-hole 400 to be opened for forming the adhesive layer. The adhesive may be a polyvinyl alcohol (PVA) or ethylene vinyl acetate (EVA)-based adhesive.

The radiant barrier sheet 20 has high tensile strength and tear strength. For example, the tensile strength of the radiant barrier sheet 20 may be in a range of about 5 kpsi to about 100 kpsi. Specifically, the tensile strength of the radiant barrier sheet 20 may be in a range of about 5 kpsi to about 40 kpsi. More specifically, the tensile strength of the radiant barrier sheet 20 may be in a range of about 10 kpsi to about 35 kpsi.

Since the radiant barrier sheet 20 has improved tensile strength and tear strength, certain fracture may be prevented during a manufacturing process of the radiant barrier sheet 20. Also, the radiant barrier sheet 20 may reinforce the strength of the wood base 10.

Particularly, since the radiant barrier sheet has the above-described number of through-holes 400 having the above-described diameter and has excellent tensile strength and tear strength, it improved moisture permeability performance and fracture does not occur during its manufacturing process.

As illustrated in FIG. 2, the radiant barrier sheet 20 comprises the protective layer 500. The protective layer 500 is disposed on the radiant reflective layer 300. The protective layer 500 protects the radiant reflective layer 300 from chemical and/or physical damage. That is, the protective layer 500 protects the radiant reflective layer 300 from erosion and/or scratches. Particularly, the protective layer 500 may prevent oxidation of the metal comprised in the radiant reflective layer.

For example, the protective layer 500 may comprise an acrylic resin, a polyurethane-based resin, an epoxy-based resin, and a nitro cellulose-based resin.

A thickness of the protective layer 500 may be about 0.001 μm or more. Specifically, the thickness of the protective layer 500 may be about 0.01 μm or more. Particularly, the thickness of the protective layer 500 may be about 0.1 μm or more. More specifically, the thickness of the protective layer 500 may be in a range of about 0.01 μm to about 1 μm.

The protective layer 500 may be formed by a process such as spray coating, slit coating, over lacquer coating, and bar coating.

As illustrated in FIG. 3, the radiant barrier sheet 20 may comprise a first protective layer 510 on a top surface of the first radiant reflective layer 310 and a second protective layer 520 on a bottom surface of the second radiant reflective layer 320.

As illustrated in FIG. 4, the protective layers 510 and 520 may cover an inner surface of the through-hole 400. Specifically, the protective layers 510 and 520 may cover all of the inner surfaces of the through-hole 400 of the polymer film and the through-holes of the radiant reflective layers. That is, the protective layers 510 and 520 may cover the inner surface of the through-hole of the first radiant reflective layer 310, the inner surface of the through-hole of the polymer film 200, and the inner surface of the through-hole of the second radiant reflective layer 320.

For example, the first radiant reflective layer 310 and/or the second radiant reflective layer 320 are stacked on the polymer film 200, and the through-hole 400 may then be formed. Thereafter, the first protective layer 510 and/or the second protective layer 520 may be formed by a coating process. The protective layers 510 and 520 may cover the inner surface of the through-hole 400 by the coating process.

Accordingly, the protective layers 510 and 520 may also protect inner side surfaces of the radiant reflective layers 310 and 320. Thus, the protective layers 510 and 520 may effectively prevent erosion occurred in the inner surfaces of the through-holes of the radiant reflective layers 310 and 320.

Since the erosion of the radiant reflective layer occurs due to the oxidation of the metal included in the radiant reflective layer, radiant reflective performance of the radiant barrier sheet may be reduced. However, in the case where the protective layers cover the inner surfaces of the through-holes of the radiant reflective layers as described above, the reduction of the radiant reflective performance of the radiant barrier sheet may be prevented. Thus, the radiant barrier sheet may have improved durability.

The radiant barrier sheet 20 may have a metal loss rate of about 10% or less. Specifically, the radiant barrier sheet 20 may have a metal loss rate of about 7% or less. More specifically, the radiant barrier sheet 20 may have a metal loss rate of about 5% or less.

The radiant barrier sheet 20 may have a solar reflectance of about 0.83% to about 0.92%. Specifically, the radiant barrier sheet 20 may have a solar reflectance of about 0.85% to about 0.90%.

The wood panel according to the present embodiment may be manufactured by the following steps.

First, a radiant barrier sheet is provided. The radiant barrier sheet may be manufactured by extrusion of a polymer resin, casting, stretching, a heat setting process, a deposition process, and a perforation process.

Specifically, the polymer resin may be prepared in the form of a film. As described above, the polymer resin may be a polyester resin formed by esterification of a diol component and dicarboxylic acid and polymerization.

The polyester resin may be melt-extruded and cooled to prepare an unstretched sheet. Thereafter, the unstretched sheet is stretched in machine direction and tenter direction and is subjected to heat setting to prepare the polymer film.

The melt-extrusion may be performed in a temperature range of Tm+30° C. to Tm+60° C. In the case where a temperature of an extruder in the melt-extrusion process is less than Tm+30° C., since the melting does not occur smoothly, viscosity of an extruded product is increased, thereby reducing productivity. In contrast, in the case where the temperature of the extruder is greater than Tm+60° C., a molecular weight of the resin may be decreased due to depolymerization caused by thermal decomposition and certain problems caused by oligomer may occur. The expression “Tm” is a melting temperature of the polymer resin.

The cooling may be performed at 30° C. or less and may be performed in a temperature range of 15° C. to 30° C.

The unstretched sheet may be uniaxially or biaxially stretched. Specifically, the unstretched sheet may be stretched about 2.5 times to about 6 times in the tenter direction and may be stretched about 2.5 times to about 6 times in the machine direction. Specifically, the unstretched sheet may be stretched about 2.7 times to about 4 times in the tenter direction and may be stretched about 2.7 times to about 4 times in the machine direction.

A stretching temperature may be in a range of Tg+5° C. to Tg+50° C. The lower the glass transition temperature (Tg) of the polymer resin is, the better the stretchability is, but fracture may occur during the preparation process. Particularly, in order to improve brittleness of the film, the unstretched sheet may be stretched in a temperature range of Tg+10° C. to Tg+40° C.

After starting the heat setting, the stretched sheet is relaxed in the machine direction and/or the tenter direction. A heat setting temperature range may be 180° C. to 245° C.

The radiant barrier sheet may be manufactured by forming a radiant reflective layer on the polymer film prepared as described above.

Furthermore, the radiant barrier sheet may be manufactured by forming a radiant reflective layer on the polymer film prepared as described above and forming a protective layer on the radiant reflective layer.

The radiant reflective layer may be formed by depositing a metal such as aluminum or copper.

The protective layer may be formed by coating an acrylic resin, a polyurethane-based resin, an epoxy-based resin, and a nitro cellulose-based resin and drying.

Thereafter, through-holes may be formed in the polymer film or the radiant barrier sheet. Specifically, the through-holes may be formed in the radiant barrier sheet on which the polymer film and the radiant reflective layer are sequentially stacked, or in the radiant barrier sheet on which the polymer film, the radiant reflective layer, and the protective layer are sequentially stacked. As a result, the radiant barrier sheet may have the through-holes that penetrate through the polymer film and the radiant reflective layer, or the through-holes that penetrate through the polymer film, the radiant reflective layer, and the protective layer.

The through-holes may be formed by laser perforation, needle perforation, or flame perforation.

A protective layer may be formed on the radiant barrier sheet comprising the radiant reflective layer and the through-holes. Thus, in the case where the protective layer is formed after the formation of the through-holes, the radiant barrier sheet having a structure illustrated in FIG. 4 may be manufactured.

Then, a wood base is provided.

After wood chips are mixed with an adhesive, the wood base may be formed by being molded in the form of a plate and cured.

Alternatively, the wood base may be formed by cutting and processing wood.

Next, a wood panel may be manufactured by heat-pressing the radiant barrier sheet and the wood base. Specifically, the radiant barrier sheet may be directly laminated on the wood base.

Alternatively, the radiant barrier sheet and the radiant reflective layer may be pressed on the wood base without forming the through-holes. The radiant barrier sheet is pressed on the wood base and the through-holes may then be formed in the radiant barrier sheet and the radiant reflective layer.

The wood panel according to the embodiment of the present invention may comprise the radiant barrier sheet which has 1 to 10 through-holes having a diameter of about 80 μm to about 300 μm per 1 cm². Accordingly, the wood panel may transmit moisture while having improved waterproof performance. As a result, the wood panel according to the present invention may easily protect the wood base from external moisture such as rain or snow. Also, the wood panel according to the present invention may easily discharge internal moisture to the outside.

The wood panel of the present invention is not easily ignited in comparison to a conventional wood panel in case of an electricity leakage or a stroke of lightning, and thus, the wood panel has good fire resistance. Also, the wood panel may have advantages such as prevention of erosion of wood achieved due to excellent moisture resistance and easy installation achieved due to excellent mechanical strength. Thus, the wood panel according to the present invention may be suitable for a roof or wall of a house.

### Mode for the Invention

Hereinafter, the present invention is explained in detail by Examples. The following Examples are intended to further illustrate the present invention without limiting its scope.

### EXAMPLES

A polyethylene terephthalate resin (product of SKC) was melt-extruded through an extruder at about 280° C. and then cooled on a casting roll at about 20° C. to prepare an unstretched sheet. The unstretched sheet thus prepared was immediately preheated to 80° C. and then stretched about 3.5 times in a machine direction and about 3.5 times in a tenter direction at about 110° C. Thereafter, the stretched sheet was subjected to heat setting at a temperature of about 220° C. for about 10 seconds. Accordingly, a PET film having a thickness of about 10 micron was prepared.

Thereafter, aluminum was vacuum-deposited on a top surface and a bottom surface of the PET film to form a radiant reflective layer having an optical density of 2.5.

Then, the PET film and the radiant reflective layer were irradiated with a laser beam to form through-holes as illustrated in the following Table 1. In such case, it was aimed at the preparation of samples having a tensile strength of 5 kpsi or more.

TABLE 1

| | | The number of | Area of | | | |
|---|---|---|---|---|---|---|
| | Through-hole | through-holes | through-holes | Moisture | Thermal | |
| Category | diameter (μm) | per cm² | per cm² (μm²) | permeability | emittance | Erosion |
| Example 1 | 100 | 5 | 40,000 | ∘ | ∘ | x |
| Example 2 | 250 | 2 | 100,000 | ⊚ | ∘ | x |
| Example 3 | 250 | 5 | 200,000 | ⊚ | ∘ | x |

As illustrated in Table 1, with respect to a radiant barrier sheet including the metal deposition layer, since erosion of the radiant reflective layer occurred due to the oxidation of the metal, there was a defect that radiant reflective capability was lost. Therefore, a protective layer was formed by coating the radiant reflective layer with a nitro cellulose resin (manufacturer: Dow Chemical, product name: WALSRODER™) using an over lacquer coating process.

TABLE 2

| | Protective | Through- | The number | Area of | | | |
|---|---|---|---|---|---|---|---|
| | layer | hole | of | through- | | | |
| | thickness | diameter | through-holes | holes per | Moisture | Thermal | |
| Category | (μm) | (μm) | per cm² | cm² (μm²) | permeability | emittance | Erosion |
| Example 4 | 0.001 | 100 | 5 | 40,000 | ∘ | ∘ | Δ |
| Example 5 | 0.005 | 100 | 5 | 40,000 | ∘ | ∘ | Δ |
| Example 6 | 0.01 | 100 | 5 | 40,000 | ∘ | ∘ | ∘ |
| Example 7 | 0.1 | 100 | 5 | 40,000 | ∘ | ∘ | ⊚ |
| Example 8 | 1 | 100 | 5 | 40,000 | ∘ | ∘ | ⊚ |
| Example 9 | 0.005 | 250 | 2 | 100,000 | ⊚ | ∘ | Δ |
| Example 10 | 0.01 | 250 | 2 | 100,000 | ⊚ | ∘ | ∘ |
| Example 11 | 0.1 | 250 | 2 | 100,000 | ⊚ | ∘ | ⊚ |
| Example 12 | 1 | 250 | 2 | 100,000 | ⊚ | ∘ | ⊚ |
| Example 13 | 0.01 | 250 | 5 | 200,000 | ⊚ | ∘ | ∘ |
| Example 14 | 1 | 250 | 5 | 200,000 | ⊚ | ∘ | ⊚ |

TABLE 3

| | | | The number of | Area of through- | |
|---|---|---|---|---|---|
| | Protective layer | Through-hole | through-holes per | holes per cm² | Solar reflectance |
| Category | thickness (μm) | diameter (μm) | cm² | (μm²) | (%) |
| Example 15 | 0.001 | 100 | 5 | 40,000 | 0.90 |
| Example 16 | 0.005 | 100 | 5 | 40,000 | 0.87 |
| Example 17 | 0.01 | 100 | 5 | 40,000 | 0.85 |

As illustrated in Table 2, the erosion of the radiant reflective layer was prevented by the protective layer.

Also, from the results of tensile strength measurements, the radiant reflective layers of Examples 1 to 17 had a tensile strength of 5 kpsi or more.

Physical Property Measurement Methods

(1) Moisture Permeability

Moisture permeability was measured according to ASTM E96 method. The result of the measurements was evaluated as “x” when the moisture permeability was 1 perm or less, as “Δ” when the moisture permeability was in a range of 1 perm to 10 perm, as “∘” when the moisture permeability was in a range of 10 perm to 25 perm, and as “⊚” when the moisture permeability was 25 perm or more.

(2) Tensile Strength

Tensile strength was measured according to ASTM D882 method.

(3) Thermal Emittance

Thermal emittance was measured according to ASTM C1313 method. The result evaluated as “x” when the thermal emittance was less than 80%, and as “∘” when the thermal emittance was 80% or more.

(4) Erosion of Radiant Reflective Layer

The erosion of the thermal reflective layer was evaluated by measuring a metal loss rate according to ASTM D3310 method. The result was evaluated as “x” when the metal loss rate was 10% or more, as “Δ” when the metal loss rate was in a range of 7% to 10%, as “∘” when the metal loss rate was in a range of 5% to 7%, and as “⊚” when the metal loss rate was 5% or less.

(5) Solar Reflectance

Solar reflectance was measured according to ASTM 1549-09 method.

1. A radiant barrier sheet comprising:
a polymer film;
a first radiant reflective layer disposed on the polymer film; and
a first protective layer disposed on the first radiant reflective layer,
wherein the radiant barrier sheet has through-holes configured to penetrate through the polymer film and the first radiant reflective layer,
the number of the through-holes ranges from 1 to 10 per 1 cm²,
a planar area of the through-holes ranges from about 20,000 μm² to about 200,000 μm² per 1 cm², and
a diameter of the through-hole ranges from about 80 μm to about 300 μm.

2. The radiant barrier sheet of claim 1, wherein a thickness of the polymer film is 5 μm or more.

3. The radiant barrier sheet of claim 1, wherein the first radiant reflective layer comprises a metal.

4. The radiant barrier sheet of claim 3, wherein the first radiant reflective layer has a thickness that satisfies a condition that an optical density of the first radiant reflective layer is 1.0 or more.

5. The radiant barrier sheet of claim 3, wherein a metal loss rate of the radiant barrier sheet is about 7% or less.

6. The radiant barrier sheet of claim 1, wherein a thickness of the first protective layer is 0.01 μm or more.

7. The radiant barrier sheet of claim 1, wherein a moisture permeability of the radiant barrier sheet is about 25 perm or more.

8. The radiant barrier sheet of claim 1, wherein the radiant barrier sheet has a thermal emittance of about 80% or more, and has a solar reflectance of about 0.83% to about 0.92%.

9. The radiant barrier sheet of claim 1, further comprising a second radiant reflective layer disposed on a bottom surface of the polymer film; and
a second protective layer disposed on a bottom surface of the second radiant reflective layer,
wherein the through-holes penetrate through the polymer film, the first radiant reflective layer, and the second radiant reflective layer.

10. The radiant barrier sheet of claim 1, wherein the planar area of the through-holes ranges from about 40,000 μm² to about 200,000 μm² per 1 cm².

11. The radiant barrier sheet of claim 1, wherein the through-holes penetrate through the polymer film, the first radiant reflective layer, and the first protective layer.

12. A wood panel comprising:
a wood base; and
a radiant barrier sheet bonded to the wood base,
wherein the radiant barrier sheet comprises a polymer film disposed on the wood base;
a first radiant reflective layer disposed on the polymer film; and
a first protective layer disposed on the first radiant reflective layer,
wherein the radiant barrier sheet has through-holes configured to penetrate through the polymer film and the first radiant reflective layer,
the number of the through-holes ranges from 1 to 10 per 1 cm²,
a planar area of the through-holes ranges from about 20,000 μm² to about 200,000 μm² per 1 cm², and
a diameter of the through-hole ranges from about 80 μm to about 300 μm.

13. The wood panel of claim 12, wherein the radiant barrier sheet further comprises a second radiant reflective layer disposed on a bottom surface of the polymer film; and
a second protective layer disposed between the second radiant reflective layer and the wood panel.

14. The wood panel of claim 13, wherein each of the first radiant reflective layer and the second radiant reflective layer comprises a metal, and
the radiant barrier sheet has a tensile strength of about 5 kpsi to about 40 kpsi.

15. The wood panel of claim 14, wherein each of the first protective layer and the second protective layer has a thickness of about 0.1 μm or more,
a metal loss rate of the radiant barrier sheet is 7% or less, and
a moisture permeability of the radiant barrier sheet is about 25 perm or more.

16. The wood panel of claim 12, wherein the first protective layer covers an inner surface of the through-hole of the first radiant reflective layer and an inner surface of the through-hole of the polymer film.

17. A radiant barrier sheet comprising:
a polymer film;
a first radiant reflective layer disposed on the polymer film; and
a first protective layer disposed on the first radiant reflective layer,
wherein the radiant barrier sheet has through-holes configured to penetrate through the polymer film and the first radiant reflective layer,
the number of the through-holes ranges from 1 to 10 per 1 cm²,
a diameter of the through-holes ranges from about 80 μm to about 300 μm, and
the first protective layer covers both an inner surface of the through-hole of the first radiant reflective layer and an inner surface of the through-hole of the polymer film.

18. The radiant barrier sheet of claim 17, further comprising a second radiant reflective layer disposed on a bottom surface of the polymer film; and
a second protective layer disposed under the second radiant reflective layer.

19. The radiant barrier sheet of claim 18, wherein each of the first protective layer and the second protective layer has a thickness of about 0.1 μm or more.

20. The radiant barrier sheet of claim 17, wherein a planar area of the through-hole ranges from about 20,000 μm² to about 200,000 μm² per 1 cm².
